(19) United States
(12) Patent Application Publication
(10) Pub. No.: US 2018/0125228 A1
(43) Pub. Date: May 10, 2018

(54) RETRACTABLE DISPLAY

(71) Applicant: AMX LLC, Richardson, TX (US)

(72) Inventors: Jomichael PORTER, Dallas, TX (US); Phong Viet-Thanh LE, Plano, TX (US); Jim LUTHER, Farmersville, TX (US); Douglas N. LAUBE, Farmersville, TX (US)

(21) Appl. No.: 15/574,141

(22) PCT Filed: Jun. 16, 2016
(86) PCT No.: PCT/US16/37924

§ 371 Date: Nov. 14, 2017

Related U.S. Application Data
(60) Provisional application No. 62/180,528, filed on Jun. 16, 2015.

(51) Int. Cl. A47B 21/007; A47B 97/00; H05K 5/00

(52) U.S. Cl. CPC A47B 21/0073; H05K 5/0017; A47B 97/001

(57) ABSTRACT

A retractable display may erect from a display housing cavity and tilt to a specified angle for optimum display characteristics. One example may include at least one of a display housing cavity, a display, a track mounted to the display inside the display housing cavity, and a lead screw disposed on the track which rotationally raises the track and the display out of the display housing cavity.

### CROSS-REFERENCE TO RELATED APPLICATIONS

This application is a national stage application under 35 USC 371 of international application no. PCT/US16/37924 filed on Jun. 16, 2016 which claims priority to earlier filed U.S. provisional patent application No. 62/180,528 filed on Jun. 16, 2015 and entitled “Touch Panels, Wireless Transmitter and Cable Overmold”, the entire contents of which are incorporated herein by reference.

### TECHNICAL FIELD OF THE APPLICATION

This application relates to a retractable display and more particular to a display which can be raised, lowered and tilted.

### BACKGROUND OF THE APPLICATION

Conventionally, the need and quantity of digital displays has continued to increase year after year. However, no matter how small the displays are made, the display still requires a significant amount of space on a desk, wall, or other surface commonly associated with a display. What is needed is a solution that overcomes these limitations.

### SUMMARY OF THE APPLICATION

One example embodiment of the present application provides an apparatus including at least one of: a display housing cavity, a display, a track mounted to the display inside the display housing cavity, and a lead screw disposed on the track which rotationally raises the track and the display out of the display housing cavity.

Another example embodiment of the present application provides an apparatus including at least one of: a display housing cavity, a track mounted inside the display housing cavity, and a lead screw disposed on the track which rotationally raises the track of the display housing cavity.

### BRIEF DESCRIPTION OF THE DRAWINGS

FIG. 1A illustrates a rear view of the display and movable track according to example embodiments.

FIG. 1B illustrates another rear view of the display and movable track according to example embodiments.

FIG. 2 illustrates a rear view of the display and movable track with a drive motor according to example embodiments.

FIG. 3 illustrates a side view of the display and movable track and a rotational tilt pin configuration according to example embodiments.

FIG. 4 illustrates a side view of the display and movable track inside a housing cavity and a rotational tilt hook configuration according to example embodiments.

FIG. 5A illustrates a side view of the display and movable track and a rotational tilt sprocket and driving belt configuration according to example embodiments.

FIG. 5B illustrates a side view of the display and movable track inside a housing cavity and a rotational roller and ramp configuration according to example embodiments.

FIG. 6A illustrates a tilt motor configuration located near the top of the display according to example embodiments.

FIG. 6B illustrates a side view of the tilt motor configuration located near the top of the display according to example embodiments.

FIG. 7 illustrates a rear view of the display in an extended and tilted position according to example embodiments.

FIG. 8 illustrates a top view of the display in a recessed position according to example embodiments.

FIG. 9 illustrates a front view of the display in an extended and tilted position according to example embodiments.

FIG. 10 illustrates a rear view of the display and movable track having a belt driving mechanism according to another example embodiment.

### DETAILED DESCRIPTION OF THE APPLICATION

It will be readily understood that the components of the present application, as generally described and illustrated in the figures herein, may be arranged and designed in a wide variety of different configurations. Thus, the following detailed description of the embodiments, as represented in the attached figures, is not intended to limit the scope of the application as claimed, but is merely representative of selected embodiments of the application.

The features, structures, or characteristics of the application described throughout this specification may be combined in any suitable manner in one or more embodiments. For example, the usage of the phrases “example embodiments”, “some embodiments”, or other similar language, throughout this specification refers to the fact that a particular feature, structure, or characteristic described in connection with the embodiment may be included in at least one embodiment of the present application. Thus, appearances of the phrases “example embodiments”, “in some embodiments”, “in other embodiments”, or other similar language, throughout this specification do not necessarily all refer to the same group of embodiments, and the described features, structures, or characteristics may be combined in any suitable manner in one or more embodiments.

According to example embodiments, a display, such as a computer monitor, a tablet computing device, a mobile device, or other device may be affixed to a track that moves up and down out of a recessed housing slot. The display may be a liquid crystal display (LCD), a light emitting diode (LED) display, a plasma display or any other compact display configuration known to those skilled in the art.

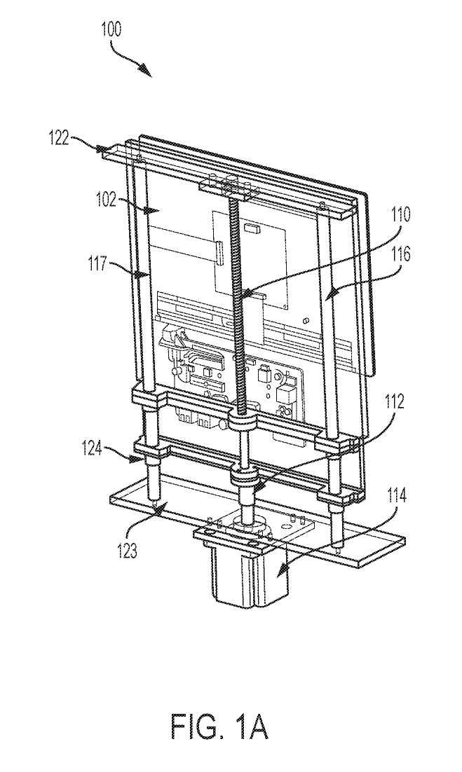

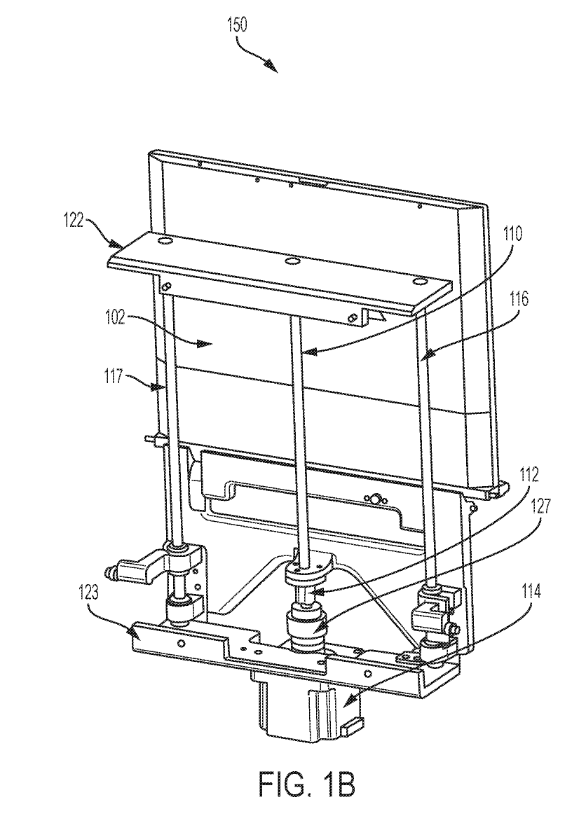

FIG. 1A illustrates a rear view of the display and movable track according to example embodiments. In FIG. 1A, the display and movable track 100 are shown without the recessed housing module. In this configuration, the display 102 is mounted to the movable track having a top securing panel 122 which is affixed to the top portion of the display, the guiding rods 116 and 117 and the lead screw 110. The guiding rods 116/117 and the lead screw 110 are mounted to the top securing panel 122 and to a bottom securing panel 123 which sits against a motor housing 114. Inside the motor housing 114 a motor turns the drive nut 112 to rotate causing the lead screw to turn and the display and movable track to move in an upward position. In this example, the motor is an in-line motor with respect to the drive nut 112. Additionally, the bushing or bearing set 124 on the guiding rods provides a support to maintain the movable track position as the motor drives the lead screw to move the display along the guiding rods.

FIG. 1B illustrates another rear view of the display and movable track with a slip clutch or safety clutch according to example embodiments. In FIG. 1B, the display and movable track 150 are shown without the recessed housing module. In this configuration, the display 102 is mounted to the movable track having a top securing panel 122 which is affixed to the top portion of the display, the guiding rods 116 and 117 and the lead screw 110. The guiding rods 116 and 117 and the lead screw 110 are mounted to the top securing panel 122 and to a bottom securing panel 123 which sits against a motor housing 114. Inside the motor housing 114 a motor turns the drive nut 112 to rotate causing the lead screw to turn and the display and movable track to move in an upward position. In this example, the motor is an in-line motor with respect to the drive nut 112. Additionally, the bushing or bearing set on the guiding rods provides a support to maintain the movable track position as the motor drives the lead screw to move the display along the guiding rods.

Below the drive nut 112 is a slip clutch 127 which is disposed between the motor housing 114 and the drive nut 112. In operation, the slip clutch 127 provides torque from the shaft of the motor 114 to the lead screw 110. If the user's finger or some other obstruction is pinched between the display 102 and the opening in the mounting surface, the clutch 127 slips causing a stoppage of further movement of the display and preventing damage or injury.

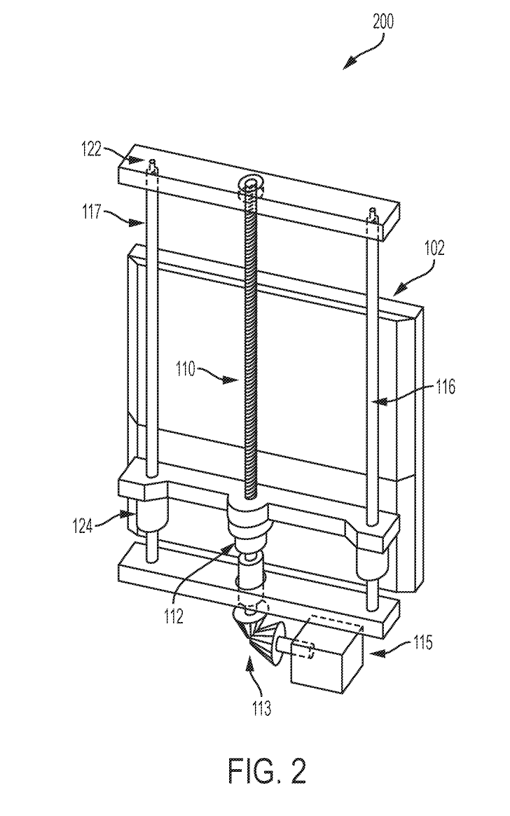

FIG. 2 illustrates a rear view 200 of the display and movable track with a drive motor according to example embodiments. Referring to FIG. 2, in this configuration the drive motor 115 is positioned 90 degrees from the lead screw 110 and the drive nut of the lead screw 112. In other embodiments, the drive motor 115 is positioned approximately 90 degrees from the lead screw 110 and the drive nut of the lead screw 112. The motor 115 will turn the bevel gear/worm gear 113 to drive the lead screw and move the movable track accordingly. The display 102 is mounted to the movable track having a top securing panel 122 which is affixed to the top portion of the display, the guiding rods 116 and 117 and the lead screw 110. The guiding rods 116/117 and the lead screw 110 are mounted to the top securing panel 122 and to a bottom securing panel 123 which sits above the motor 115 and gear/worm gear 113. The motor 115 turns the drive nut 112 to rotate causing the lead screw to turn and the display and movable track to move in an upward position.

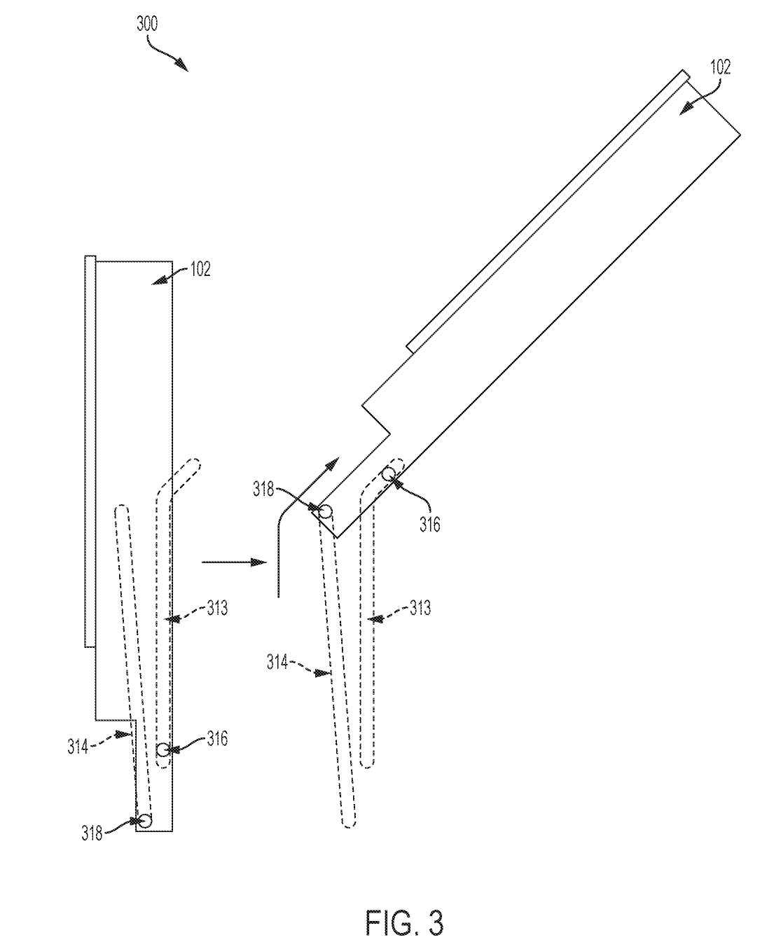

FIG. 3 illustrates a side view of the display and movable track and a rotational tilt pin configuration according to example embodiments. Referring to FIG. 3, the side view 300 illustrates the display 102 moving and tilting its axis along a two-track pivot-pin configuration. A first track 314 is a straight track which permits the first pin 318 affixed to the display track to move up and down accordingly. The second track 313 has an angled curve near a top portion of the track so the second pin 316 may travel along the curved portion to set the display at an angle with respect to the starting position.

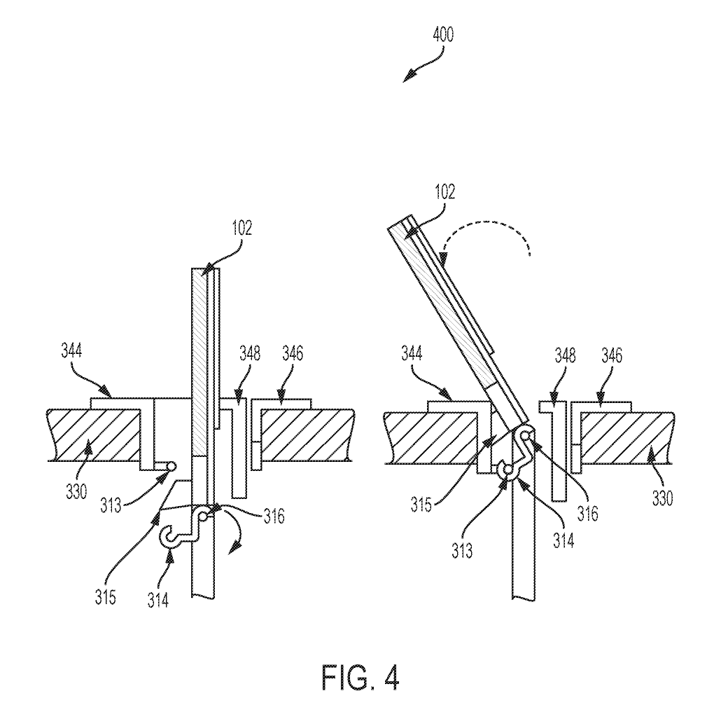

FIG. 4 illustrates a side view of the display and movable track inside a housing cavity and a rotational tilt hook configuration according to example embodiments. Referring to FIG. 4, the display tilt configuration 400 includes a collar 344 and 346 which supports the display housing cavity in position on a flat surface, such as a table or desk. A support lip 348 may enable the display 102 to be tilted by guiding the display 102 upward and holding the display 102 in-place once in a resting position as indicated by the arrow. The support lip 348 is a gap-filling support structure that provides needed support when the display 102 is tilted backwards. The surface 330 supports the collar 344 to make a substantially planar collar which is not disruptive to surface of the desk. In operation, the display is shifted upward and then a pivot point bolt 316 provides a rotational axis for the display to bend enough to engage the hook 314 against the round bar 313 to secure the tilting position. Also, a support wedge 315 offers an angled surface to hold the tilted position firmly against the collar 344 of the display housing.

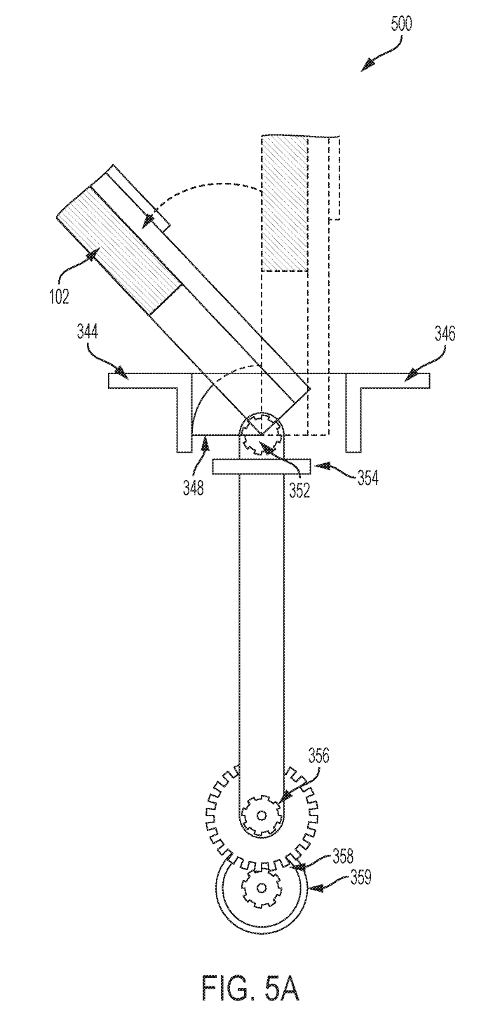

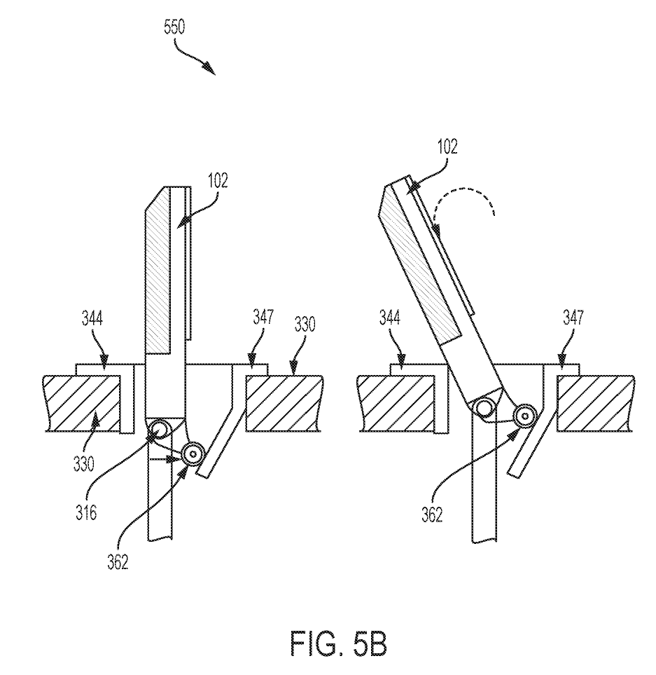

FIG. 5A illustrates a side view of the display and movable track and a rotational tilt sprocket and driving belt configuration according to example embodiments. In this configuration 500 a motor and drive belt are used to tilt the display at an angle. The collar portions 344/346 of the housing and the wedge 348 are illustrated along with the pivot location 352 and a platform 354 lifted by the lead screw to mount the upper sprocket of the pivot location 352. In operation, the drive belt 356 moves along the upper sprocket of pivot location 352 and a lower sprocket 356 both of which are rotated by the drive belt via a gear reduction configuration 358 and motor 359. The motor and gear reduction may travel vertically with the display and mount as the display is presented out of the housing and then tilted per the preference of the user. The tilted position is supported by a wedge 348

FIG. 5B illustrates a side view of the display and movable track inside a housing cavity and a rotational roller and ramp configuration according to example embodiments. In this configuration, the tilt mechanism 550 includes a heavily loaded torsion spring 316 with an attached roller 362 configured to travel up a ramp which may be part of the housing collar 347. As the roller touches the top of the ramp, a vertical wall creates a hard stop which holds the display in position. The collar 344 provides support for the display housing against the surface 330.

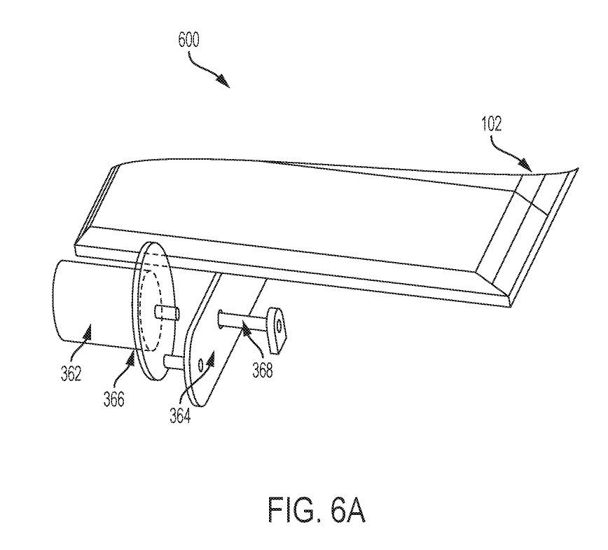

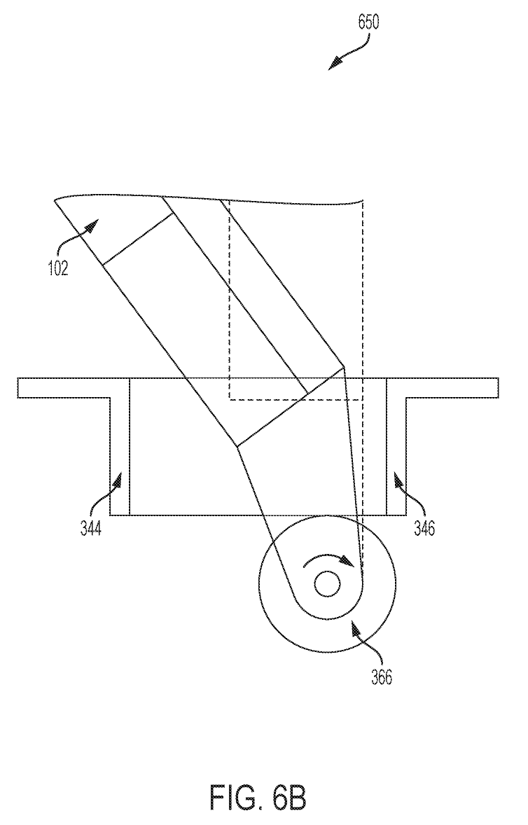

FIG. 6A illustrates a tilt motor configuration located near the top of the display according to example embodiments. Referring to FIG. 6A, the configuration 600 includes a local motor or tilt motor 362 mounted at the bottom of the display 102 which turns a wheel or tilt cam 366 connected to a turning rod affixed to the display support or tilt arm 364. The motor 362 will move to tilt the display via a direct connection to the display mount and support 368 or tilt pivot shaft.

FIG. 6B illustrates a side view of the tilt motor configuration located near the top of the display according to example embodiments. Referring to FIG. 6B, the configuration 650 includes the display 102 tilted by the tilt motor 366 flywheel to a desired position. The collars 344 and 246 do not interfere with the movement of the display and provide support for the display housing.

In one example embodiment, a display housing cavity may house the display. A track may be mounted to the display inside the display housing cavity and a lead screw is disposed on the track which rotationally raises the track and the display out of the display housing cavity. Among various different embodiments, a motor is disposed in the display housing cavity, and a rotational drive nut is connected to the lead screw and is rotated by the motor to raise the track and the display out of the display housing cavity. The motor may be an inline drive motor disposed directly under the lead screw which is disposed in a center portion of the track and the display housing cavity. The motor may also be a 90 degree drive motor disposed under the track which is also configured to raise the drive nut. At least one guiding rod and bushing are disposed in parallel with the lead screw to guide the track and the display out of the display housing cavity. A tilt rotation motor may include a rotational axis to rotate the display once the display is erected outside the display housing cavity. Also, in another example, a two-pin two-track tilt mechanism is used where one track is uniform and the second track has a curved top portion permitting a top pin to secure a tilted position in the second track.

A wedge may also be disposed on the track and a round bar and hook tilt mechanism can be used so the hook rests against the round bar and the wedge rests against a surface of the display housing cavity to secure a tilted position of the display. Also, a torsion spring may be used and a ramp affixed to a surface of the display housing may be used along with a roller affixed to the torsion spring to secure a tilted position of the display against the ramp. Also, a tilt motor may be used with a drive belt and a top sprocket may be affixed to the display on a first end of the drive belt, and a bottom sprocket may be affixed to the tilt motor on a second end of the drive belt to rotate a tilted position of the display.

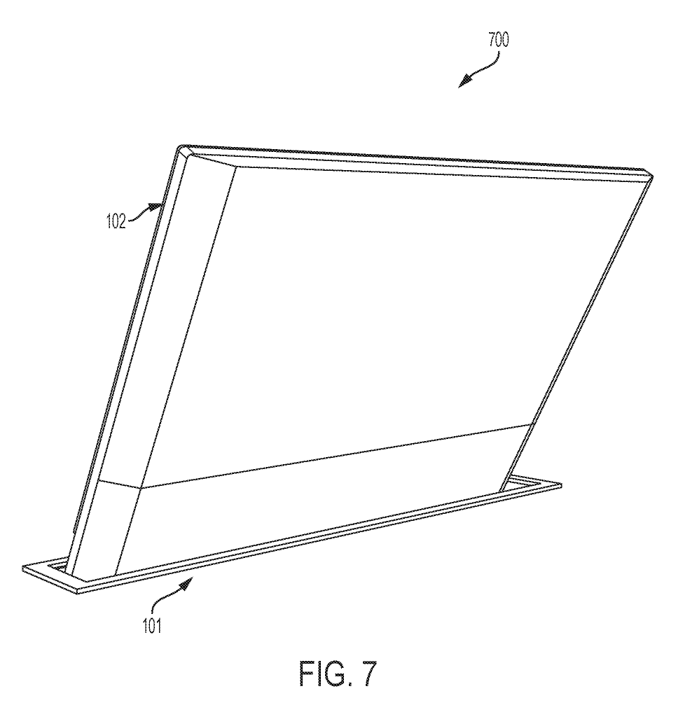

FIG. 7 illustrates a rear view of the display in an extended and tilted position according to example embodiments. Referring to FIG. 7, the rear view 700 illustrates the rear view of the display 102 after it has exited and tilted out of the display housing collar 101 which would ideally be flush with a desk, table or wall permitting the display to be used and retracted when not in use.

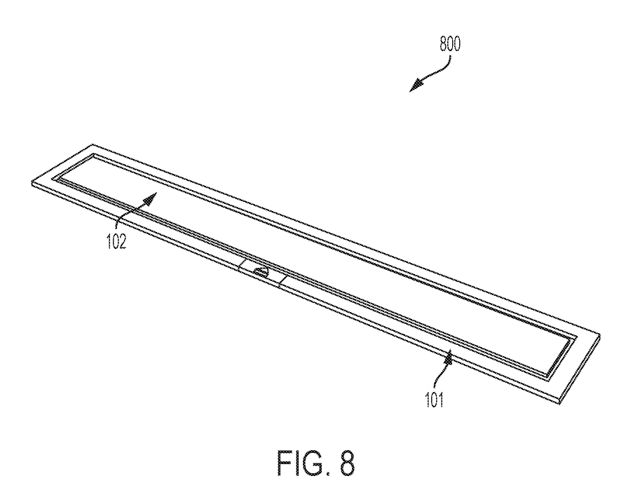

FIG. 8 illustrates a top view of the display in a recessed position according to example embodiments. In FIG. 8, the example 800 has the top of the display 102 depressed into the recess housing and in a manner that is flush with the display housing collar 101.

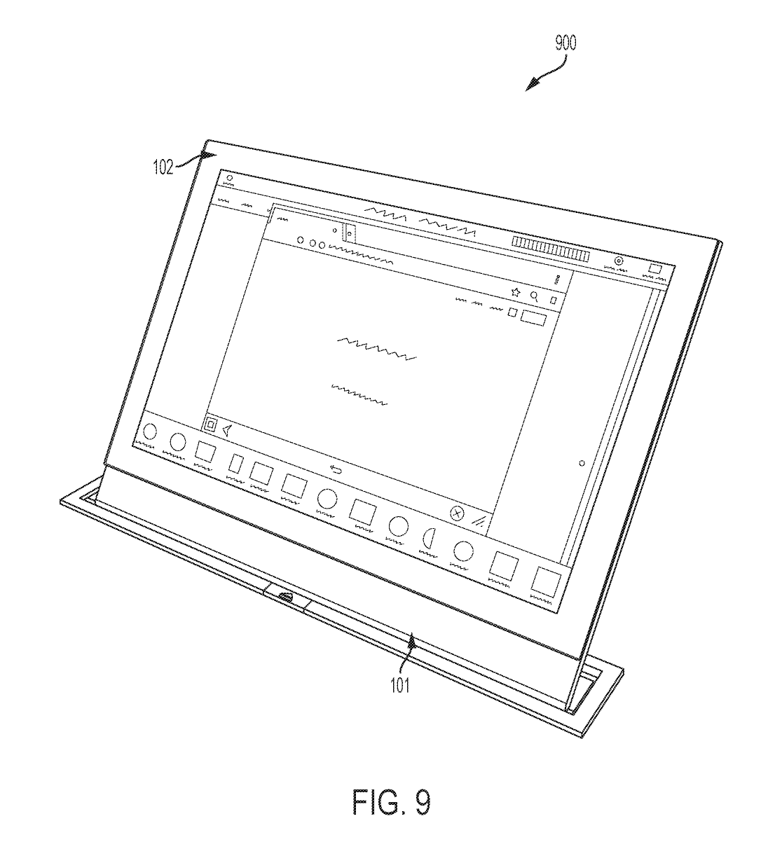

FIG. 9 illustrates a front view of the display in an extended and tilted position according to example embodiments. The display is fully erected and tilted out from the display housing cavity. The display may be erected from its cavity housing in a straight position, a slightly modified position (i.e., tilted position), a large degree of tilt, etc., depending on the user's preferences.

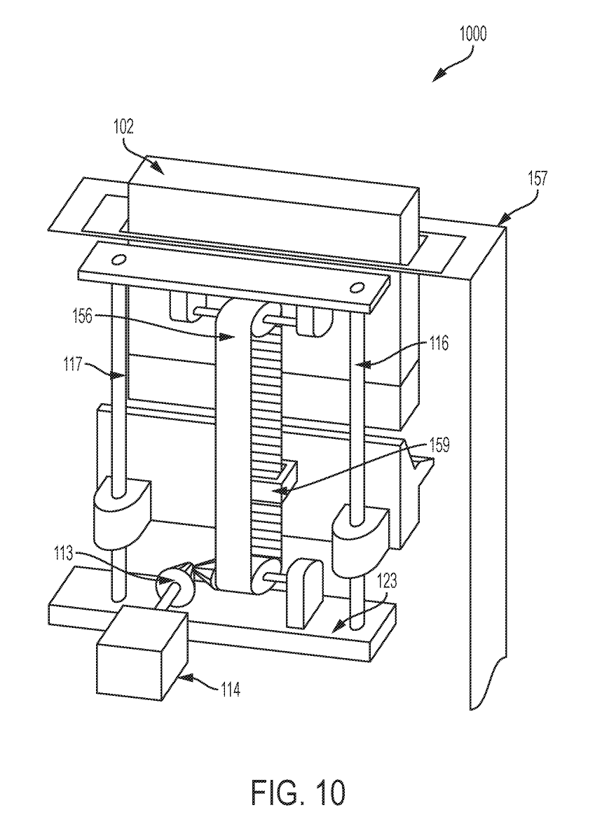

FIG. 10 illustrates a rear view of the display and movable track having a belt driving mechanism according to another example embodiment. Referring to FIG. 10, in this configuration 1000 the motor 114 is rotated 90 degrees (or approximately 90 degrees) from the planar area of the display 102 and display housing. This enables some distance to be afforded when embedding the display housing into a console 157. The console 157 (and display) may be part of an automobile, airplane, train, bus, or other transport with limited space. For example, the console 157 may be in and/or on a compact surface such as a dash, wall, seat or other location of a transport. The drive motor 114 would drive a pulley and timing belt or driving belt 156 that would be clamped to a lifting frame of the display via a clamp 159 which moves with the driving belt 156. The drive motor 114 is positioned 90 degrees from the driving belt 156. The motor 114 will turn the bevel gear/worm gear 113 to drive the driving belt 156 and move the movable track upward and downward accordingly. The display 102 is mounted to the movable track, and the guiding rods 116 and 117 permit the display and housing to move up and down in a uniform manner. The guiding rods 116 and 117 are mounted to the top securing panel and to a bottom securing panel 123. The motor 114 turns the driving belt 156 to rotate causing the display and movable track to move in an upward position.

It will be readily understood that the components of the application, as generally described and illustrated in the figures herein, may be arranged and designed in a wide variety of different configurations. Thus, the detailed description of the embodiments is not intended to limit the scope of the application as claimed, but is merely representative of selected embodiments of the application.

One having ordinary skill in the art will readily understand that the application as discussed above may be practiced with steps in a different order, and/or with hardware elements in configurations that are different than those which are disclosed. Therefore, although the application has been described based upon these preferred embodiments, it would be apparent to those of skill in the art that certain modifications, variations, and alternative constructions would be apparent, while remaining within the spirit and scope of the application. In order to determine the metes and bounds of the application, therefore, reference should be made to the appended claims.

While preferred embodiments of the present application have been described, it is to be understood that the embodiments described are illustrative only and the scope of the application is to be defined solely by the appended claims when considered with a full range of equivalents and modifications thereto.

What is claimed is:

1. An apparatus, comprising:
a display housing cavity;
a display;
a track mounted to the display inside the display housing cavity; and
a lead screw disposed on the track which rotationally raises the track and the display out of the display housing cavity.

2. The apparatus of claim 1, further comprising:
a motor disposed in the display housing cavity; and
a rotational drive nut connected to the lead screw and rotated by the motor to raise the track and the display out of the display housing cavity.

3. The apparatus of claim 2, wherein the motor is an inline drive motor disposed directly under the lead screw which is disposed in a center portion of the track and the display housing cavity.

4. The apparatus of claim 2, wherein the motor is a 90 degree drive motor disposed under the track.

5. The apparatus of claim 1, further comprising:
at least one guiding rod and bushing disposed in parallel with the lead screw to guide the track and the display out of the display housing cavity.

6. The apparatus of claim 1, further comprising:
a tilt rotation motor comprising a rotational axis to rotate the display once the display is erected outside the display housing cavity.

7. The apparatus of claim 1, further comprising:
a two-pin two-track tilt mechanism wherein one track is uniform and the second track has a curved top portion which permits a top pin to secure a tilted position in the second track.

8. The apparatus of claim 1, further comprising:
a wedge disposed on the track; and
a round bar and hook tilt mechanism wherein the hook rests against the round bar and the wedge rests against a surface of the display housing cavity to secure a tilted position of the display.

9. The apparatus of claim 1, further comprising:
a torsion spring;
a ramp affixed to a surface of the display housing; and
a roller affixed to the torsion spring to secure a tilted position of the display against the ramp.

10. The apparatus of claim 1, further comprising:
a tilt motor;
a drive belt;
a top sprocket affixed to the display on a first end of the drive belt; and
a bottom sprocket affixed to the tilt motor on a second end of the drive belt to rotate a tilted position of the display.

11. An apparatus, comprising:
a display housing cavity;
a track mounted inside the display housing cavity; and
a lead screw disposed on the track which rotationally raises the track of the display housing cavity.

12. The apparatus of claim 11, further comprising:
a motor disposed in the display housing cavity; and
a rotational drive nut connected to the lead screw and rotated by the motor to raise the track and a display out of the display housing cavity, wherein the track is mounted to the display.

13. The apparatus of claim 12, wherein the motor is an inline drive motor disposed directly under the lead screw which is disposed in a center portion of the track and the display housing cavity.

14. The apparatus of claim 12, wherein the motor is a 90 degree drive motor disposed under the track.

15. The apparatus of claim 12, further comprising:
at least one guiding rod and bushing disposed in parallel with the lead screw to guide the track and the display out of the display housing cavity.

16. The apparatus of claim 12, further comprising:
a tilt rotation motor comprising a rotational axis to rotate the display once the display is erected outside the display housing cavity.

17. The apparatus of claim 11, further comprising:
a two-pin two-track tilt mechanism wherein one track is uniform and the second track has a curved top portion which permits a top pin to secure a tilted position in the second track.

18. The apparatus of claim 12, further comprising:
a wedge disposed on the track; and
a round bar and hook tilt mechanism wherein the hook rests against the round bar and the wedge rests against a surface of the display housing cavity to secure a tilted position of the display.

19. The apparatus of claim 12, further comprising:
a torsion spring;
a ramp affixed to a surface of the display housing; and
a roller affixed to the torsion spring to secure a tilted position of the display against the ramp.

20. The apparatus of claim 12, further comprising:
a tilt motor;
a drive belt;
a top sprocket affixed to the display on a first end of the drive belt; and
a bottom sprocket affixed to the tilt motor on a second end of the drive belt to rotate a tilted position of the display.
